(19) United States
(12) Patent Application Publication
(10) Pub. No.: US 2008/0035368 A1
(43) Pub. Date: Feb. 14, 2008

(54) Chip holder board

(76) Inventor: Sen-Sung Lin, Wujih Hsiang (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/500,968

(22) Filed: Aug. 9, 2006

(51) Int. Cl. H05K 1/03

(52) U.S. Cl. 174/255; 174/262; 174/264

(57) ABSTRACT

A chip holder board for carrying chips for covering with a silver glue is disclosed to have a metal board, which has arrays of transversely longitudinally aligned through holes cutting through the top and bottom walls thereof, and a flexible polymeric covering material covered over the top and bottom walls and the periphery of the inner diameter of each of the through holes of the metal board.

### BACKGROUND OF THE INVENTION

1. Field of the Invention

The present invention relates to a chip holder board for holding chips for coating with a silver glue and more particularly, to such a chip holder board, which allows both ends of each chip carried there on to be respectively coated with a silver glue.

2. Description of the Related Art

FIG. 1 shows a chip holder board for holding chips for coating with a silver glue. According to this design, the chip holder board comprises a plastic board 1, which has through holes 2 cut through the top and bottom walls thereof, and a substantially rectangular metal open frame 3 fixedly fastened to the border of the plastic board 1. When in use, chips 4 are respectively inserted into the through holes 2, and then the chip holder board is put in a silver glue carriage to dip one end of each of the chips 4 in the silver glue 5 in the silver glue carriage, enabling the respective end of each of the chips 4 to be respectively covered with a layer of the silver glue 5 (see FIG. 2).

The aforesaid chip holder board is still not satisfactory in function. One drawback of this design of chip holder board is its great thickness and heavy weight. In order to provide the desired structural strength, the plastic board must have a certain thickness. Another drawback of this design of chip holder board is that the chip holder board allows only one end of each installed chip to be exposed to the outside for dipping in the silver glue. The silver glue coating procedure will be complicated if both ends of each chip are to be coated with the silver glue.

### SUMMARY OF THE INVENTION

The present invention has been accomplished under the circumstances in view. It is therefore the main object of the present invention to provide a chip holder board, which allows both ends of each chip carried there on to be respectively coated with a silver glue.

To achieve this and other objects of the present invention, the chip holder board comprises a metal board, which has arrays of transversely longitudinally aligned through holes cutting through the top and bottom walls thereof, and a flexible polymeric covering material covered over the top and bottom walls and the periphery of the inner diameter of each of the through holes of the metal board.

### BRIEF DESCRIPTION OF THE DRAWINGS

FIG. 1 is an oblique elevation of a chip holder board according to the prior art.

FIG. 2 is a schematic section view showing chips carried in the chip holder board and dipped in a silver glue in a silver glue carriage according to the prior art.

FIG. 3 is an oblique elevation of a metal board for chip holder board according to the present invention.

FIG. 4 is an oblique elevation of a chip holder board according to the present invention.

FIG. 5 is a schematic drawing showing chips carried in the chip holder board and dipped in a silver glue in a silver glue carriage.

FIG. 6 corresponds to FIG. 5, showing the chip holder board turned upside down.

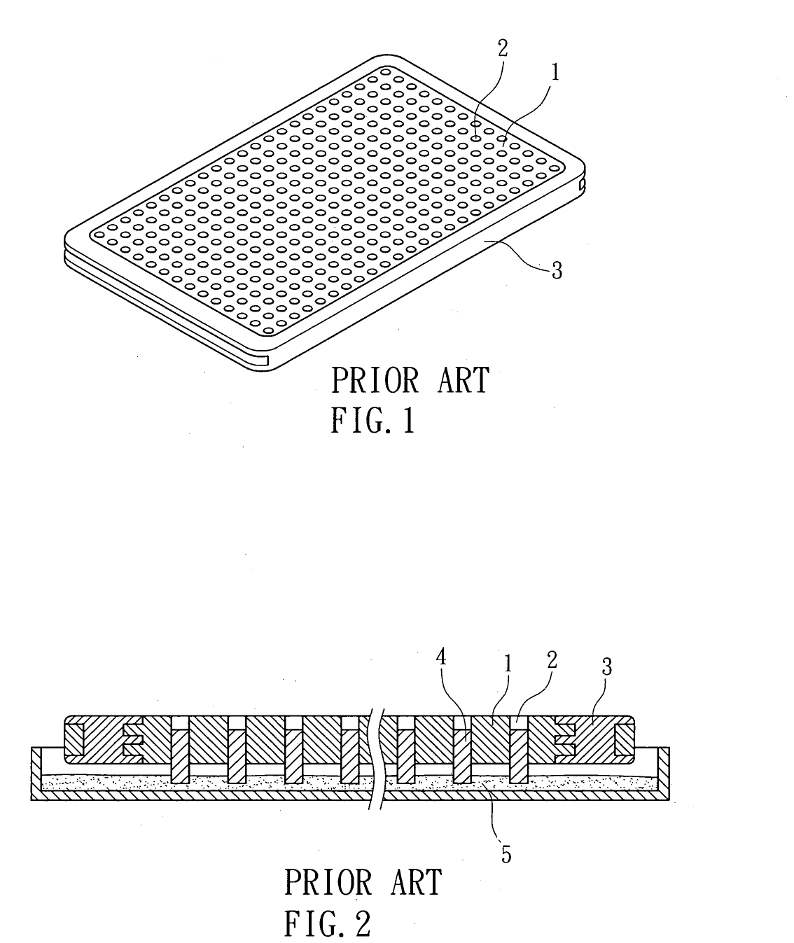

### DETAILED DESCRIPTION OF THE PREFERRED EMBODIMENT

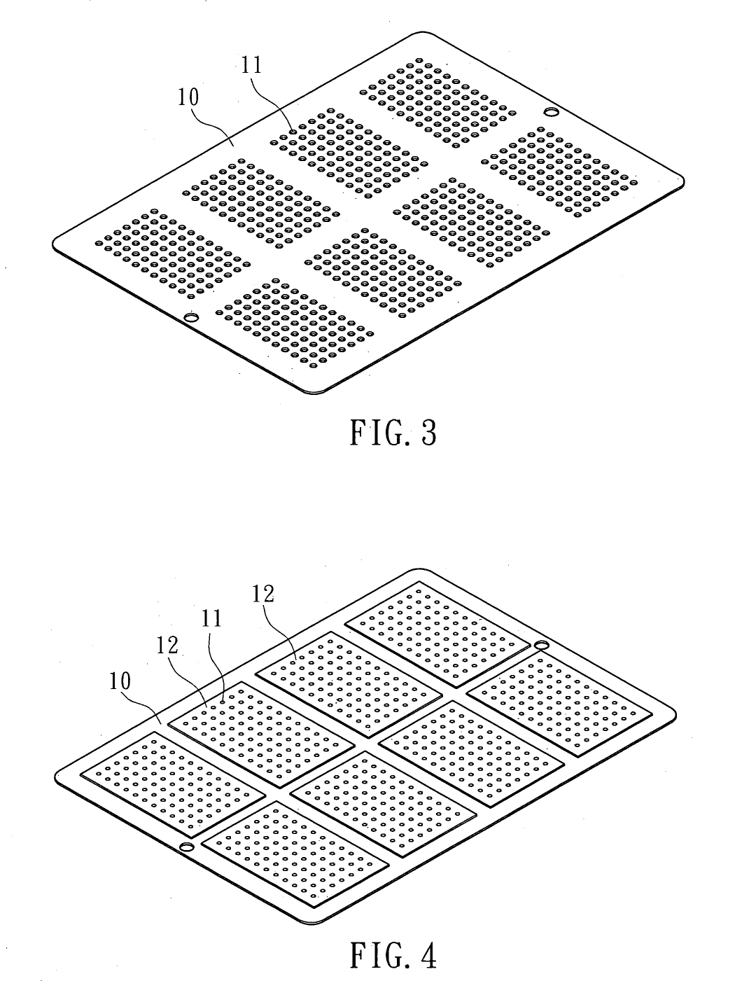

Referring to FIGS. 3 and 4, a chip holder board in accordance with the present invention is shown comprising a metal board 10, which has arrays of transversely longitudinally aligned through holes 11 cutting through the top and bottom walls thereof, and a flexible polymeric covering material 12 covered over the top and bottom walls of the metal board 10 and the periphery of the inner diameter of each through hole 11. The metal board 10 is preferably made of steel for the advantage of high structural strength. The flexible polymeric covering material 12 is directly molded on the metal board 10 with a molding apparatus.

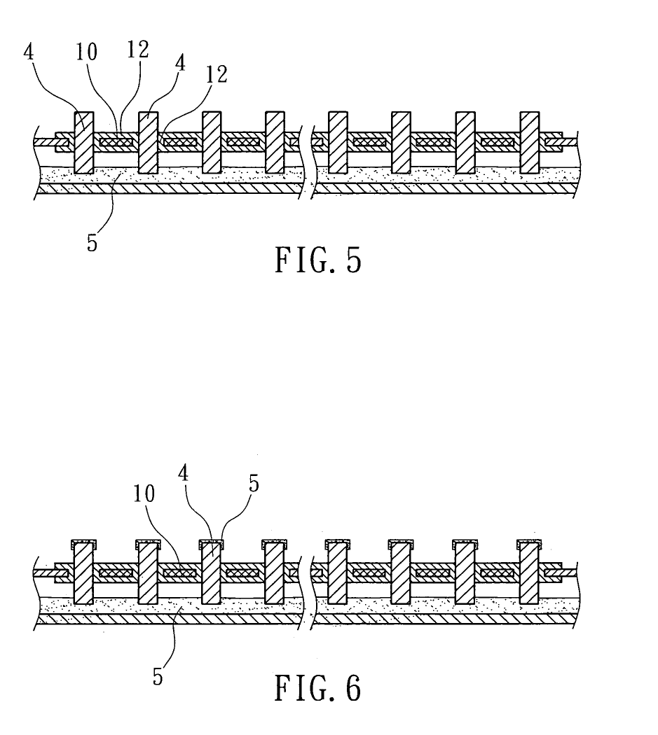

When in use, chips 4 are respectively inserted through the through holes defined in the flexible polymeric covering material 12 corresponding to the through holes 11 of the metal board 10, and then the chip holder board is put in a silver glue carriage to dip the chips 4 partially in the silver glue 5 in the silver glue carriage, enabling the respective end of each of the chips 4 to be respectively covered with a layer of the silver glue 5 (see FIG. 5). Thereafter, the chip holder board is turned upside down to have the other end of each of the chips 4 to be respectively covered with a layer of the silver glue 5 (see FIG. 6). Because the flexible polymeric covering material is covered on the top and bottom side of the chip holder board and the periphery of the inner diameter of each of the through holes, the flexible polymeric covering material holds the inserted chips firmly in place with the two distal ends of each chip respectively protruding over the top and bottom sides of the chip holder board for dipping in the silver glue.

A prototype of chip holder board has been constructed with the features of FIGS. 3˜6. The chip holder board functions smoothly to provide all of the features discussed earlier.

Although a particular embodiment of the inventions has been described in detail for purposes of illustration, various modifications and enhancements may be made without departing from the spirit and scope of the invention. Accordingly, the invention is not to be limited except as by the appended claims.

What the invention claimed is:

1. A chip holder board comprising:
a metal board, said metal board having arrays of transversely longitudinally aligned through holes cutting through top and bottom walls thereof; and
a flexible polymeric covering material covered over top and bottom walls of said metal board and the periphery of the inner diameter of each of the through holes of said metal board.
